(19) United States
(12) Patent Application Publication
(10) Pub. No.: US 2009/0231795 A1
(43) Pub. Date: Sep. 17, 2009

(54) Ergonomic adjustable screen-view technology

(76) Inventor: Charles Eric Green, Louisville, KY (US)

Correspondence Address: Charles Eric Green, 3909 Handley Ave, Louisville, KY, 40218, US

(21) Appl. No.: 12/074,748

(22) Filed: Mar. 7, 2008

(51) Int. Cl. G06F 1/16; H05K 7/00

(52) U.S. Cl. 361/679.27

(57) ABSTRACT

Laptop screens provide very limited design for use away from a work station. The use of a Laptop can become very discomforting when traveling or away form your workstation. The screen provides limited adjustability to meet the need for better posture. In an alternative embodiment, an Ergonomic Adjustable Screen-view Technology (EAST) has the potential to minimize some of the neck and shoulder discomfort while using a Laptop.

### BACKGROUND OF THE INVENTION

1. Field of the Invention

The present invention relates to Laptop screens and more particularly pertains to improving the Ergonomic Screen-view options for laptops.

2. Description of the Prior Art

The use of laptop computers is known in the prior art. Typical examples of well designed laptops are to be found in U.S. Pat. Off They are manufactured by multiple manufactures using the same basic elevation screen-view design. There are other attachments that have been designed to assist with the limitations of the current laptop screen design. The Ergonomic Notebook Riser is being manufactured by many companies most have a paten pending status. It is compatible with all laptops & docking stations. It has the height adjustable capacity of 4 to 6 inches. This is a stand along and separate Ergonomic platform to assist in the desire to have adjustable viewing options with the laptop. By the same token, there are other adjustable laptop risers designed to place the laptop at a comfortable viewing height to help prevent neck strain. Designed to elevate laptops to their maximize efficiency. Adjustable risers even tilt to help find the optimal viewing angle.

However, both of these above-described designs do not take into account the mobile laptop user. More specifically, these risers are not designed for mobile use. They are made of plastic and would possible break or crack from constant packing, movement, and might be considered another bag for airport travel. As such, it would appear that there exists a continuing need for new and improved ergonomic designs for laptop viewing and in this regard, the present invention substantially fulfills this need.

### SUMMARY OF THE INVENTION

In view of the foregoing disadvantages inherent in the known types of laptop screens and laptop risers, the present invention provides an improved Ergonomic Adjustable Screen-view construction wherein the same size of the current laptop designs. As such, the general purpose of the present invention, which will be described subsequently in greater detail, is to provide a new and improved ergonomic adjustable screen-view which has all the advantages of the prior art laptop screens and risers and none of the disadvantages. To attain this, the present invention essentially consists of a laptop screen and a laptop base which are provided with a sliding capability to move the screen up and down as to provide variable degrees of viewing options for a user. Unfortunately, any kind of extended computer use can be hard on the body, but prolonged laptop use can be especially stressful to the body. A Cornell University ergonomics study found the root cause is the laptop computer itself. “The reason is simple-with a fixed design, if the keyboard is in an optimal position for the user, the screen isn't if the screen is optimal, the keyboard isn't . . . laptops are excluded form current ergonomic design requirements . . . none of the designs satisfy this basic need.”

There has thus been outlined, rather broadly, the more important features of the invention in order that the detailed description thereof that follows may be better understood, and in order that the present contribution to the art may be better appreciated. There are, of course, additional features of the invention that will be described hereinafter and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

Further, the purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

It is therefore an object of the present invention to provide a new and improved ergonomic adjustable screen-view technology which has all the advantages of the prior art design and none of the disadvantages.

It is another object of the present invention to provide a new and improved ergonomic adjustable screen-view technology which may be easily and efficiently manufactured and marketed.

It is a further object of the present invention to provide a new and improved ergonomic adjustable screen-view technology which is of a durable and reliable construction.

An even further object of the present invention is to provide a new and improved ergonomic adjustable screen-view technology which is susceptible of a low cost of manufacture with regard to both materials and labor, and which accordingly is then susceptible of low prices of sale to the consuming public, thereby making such ergonomic adjustable screen-view technology available to the buying public.

Still yet another object of the present invention is to provide a new and improved which provides in the ergonomic adjustable screen-view technology apparatuses and methods of the prior art some of the advantages thereof, while simultaneously overcoming some of the disadvantages normally associated therewith.

Still another object of the present invention is to provide a new and improved which has variable layers of ergonomic adjustable screen-view technology so as to vary the viewing option and less strain for a user's body.

These together with other objects of the invention, along with the various features of novelty which characterize the invention, are pointed out with particularity in the claims annexed to and forming a part of this disclosure. For a better understanding of the invention, its operating advantages and the specific objects attained by its uses, reference should be had to the accompanying drawings and descriptive matter in which there is an illustrated preferred embodiment of the invention.

### BRIEF DESCRIPTION OF THE DRAWINGS

The invention will be better understood and objects other than those set forth above will become apparent when consideration is given to the following detailed description thereof Such description makes reference to the annexed drawings wherein:

FIG. 1 is a perspective view of the current laptop screen-view.

FIG. 2 is a perspective view of a new and improved first embodiment of ergonomic adjustable screen-view partially elevated.

FIG. 3 is a perspective view of the new and improved invention at its highest elevation.

### DESCRIPTION OF THE PREFERRED EMBODIMENT

With reference now to the drawings, and in particular to FIGS. 2 and 3 thereof, a new and improved ergonomic adjustable screen-view technology embodying the principles and concepts of the present invention and generally designated by the reference name EAST will be described.

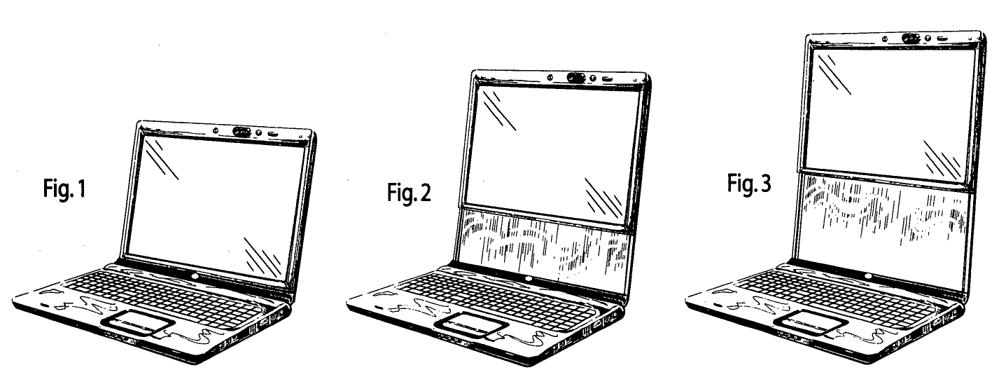

More specifically, it will be noted that the ergonomic adjustable screen-view technology is divided into 2 parts with one capable of upward movement. The base of the laptop screen will be referenced to FIG. 1 of the drawings. The adjustable screen which provides the ergonomic options will reference to FIGS. 2, and 3 of the drawing.

To obtain these varying degrees of adjustable effect, a multi-layered construction is utilized. With particular reference to FIGS. 2 and 3 of the drawings, it will be seen that the ergonomic adjustable screen-view technology in one preferred embodiment is provided with the ability to elevate up and down. This adjustable feature could consist of any known adjustable sliding or adjustable design which is generally suitable for the intended purpose.

As to the manner of usage and operation of the present invention, the same should be apparent from the above description. Accordingly, no further discussion relating to the manner of usage and operation will be provided.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed as being new and desired to be protected by Letters Patent of the U.S. is as follows:

1. A new and improved Laptop adjustable screen designed to elevate nine or more inches in height:
(a) An adjustable screen that is not an attachment but part of the original laptop/notebook design;
(b) An adjustable screen that will adjust upward and downward based on the design without the need to use any tools;
(c) An adjustable screen that is the same size as the current laptop screen
(d) Laptop top slide design is the base which would allow the screen to slide up or down to is original position.

2. The new and improved Laptop adjustable screen for use with the adjustable screen as described in claim 1, wherein said Laptop could still be used as it is currently designed at a work station.

3. The new and improved Laptop adjustable screen described in claim 1, wherein the height of each section of the Laptop and adjustable screen are the same allowing the screen to rise up several inches higher.

4. The new and improved Laptop adjustable screen described in claim 1, wherein the width of each section of the sliding screen is the same allowing the upper part to fit into the main module of the Laptop screen.

5. The new and improved Adjustable Screen-view as described in claim 1, for travel or workstation use will provide more Ergonomic Screen-view options.
